(19) United States
(12) Patent Application Publication
(10) Pub. No.: US 2014/0055761 A1
(43) Pub. Date: Feb. 27, 2014

(54) LIQUID IMMERSION EXPOSURE APPARATUS

(71) Applicant: KABUSHIKI KAISHA TOSHIBA, Tokyo (JP)

(72) Inventor: Kenji Furusho, Ooita (JP)

(73) Assignee: KABUSHIKI KAISHA TOSHIBA, Tokyo (JP)

(21) Appl. No.: 13/779,619

(22) Filed: Feb. 27, 2013

(30) Foreign Application Priority Data
Aug. 27, 2012 (JP) 2012-186847

(51) Int. Cl. G03F 7/20

(52) U.S. Cl. CPC G03F 7/70341
USPC 355/30

(57) ABSTRACT

Provided is a liquid immersion exposure apparatus which is configured to include a table, a plate, an illumination unit, an exposure position movement unit, and relative position change units. A substrate is mounted on the table. An opening portion surrounding a circumferential edge portion of the substrate mounted on the table is installed in the plate. The illumination unit forms a liquid immersion area filled with liquid immersion water at an exposure position of the substrate mounted on the table, and the illumination unit illuminates an exposure light beam on the exposure position through the liquid immersion area. The exposure position movement unit moves the exposure position. The relative position change units change a relative position between the table and the plate.

### CROSS-REFERENCE TO RELATED APPLICATIONS

This application is based upon and claims the benefit of priority from Japanese Patent Application No. 2012-186847, filed on Aug. 27, 2012; the entire contents of which are incorporated herein by reference.

### FIELD

Embodiments described herein relate generally to a liquid immersion exposure apparatus.

### BACKGROUND

In the related art, there is a known exposure apparatus which transfers a device pattern on a to-be-exposed substrate such as a semiconductor wafer by illuminating an exposure light beam beyond a reticle on which the device pattern is formed. In addition, there is a liquid immersion exposure apparatus which can transfer a finer device pattern by performing exposure in a state where a space between a projection lens projecting an exposure light beam on a to-be-exposed substrate and an exposure surface of the substrate is filled with liquid immersion water.

The liquid immersion exposure apparatus is configured to include a table on which the to-be-exposed substrate is mounted and a plate where an opening portion surrounding a circumferential edge portion of the substrate mounted on the table is installed and which is disposed at a height substantially equal to the height of the front surface of the substrate mounted on the table within the opening portion.

In addition, the liquid immersion exposure apparatus forms a liquid immersion area between the projection lens and the exposure surface by concurrently performing supplying and recovering of the liquid immersion water in the space between the projection lens and the exposure surface and transfers the device pattern while scanning the front surface of the substrate with the exposure light beam which is illuminated through the liquid immersion water.

However, the liquid immersion exposure apparatus has a problem in that, when the exposure light beam traverses a gap between an outer circumferential surface of the substrate mounted on the table and an inner circumferential surface of the opening portion in the plate, turbulence of the liquid immersion water occurs, and thus, defects occurs in the transferred device pattern.

For example, in the case where bubbles are mixed into the liquid immersion area due to the turbulence of the liquid immersion water, the refractive index with respect to the exposure light beam is changed due to the bubbles, so that defects may occur in the device pattern. In addition, in the case where the liquid immersion water is not normally recovered but remains on the front surface of the substrate due to the turbulence of the liquid immersion water, defects may also occur in the device pattern.

### BRIEF DESCRIPTION OF THE DRAWINGS

FIG. 1 is a diagram illustrating a liquid immersion exposure apparatus according to a first embodiment;

FIG. 2 is a top diagram illustrating a table and plate of the liquid immersion exposure apparatus according to the first embodiment;

FIG. 3 is a diagram illustrating a structure in the vicinity of a projection lens according to the first embodiment;

FIG. 4 is a diagram illustrating an example of a situation where turbulence of liquid immersion water occurs in the liquid immersion exposure apparatus according to the first embodiment;

FIGS. 5A to 5C, FIGS. 6A to 6C, and FIGS. 7A and 7B are diagrams illustrating an example of operations of the liquid immersion exposure apparatus according to the first embodiment;

FIG. 8 is a diagram illustrating a liquid immersion exposure apparatus according to a second embodiment; and

FIG. 9 is a diagram illustrating a liquid immersion exposure apparatus according to a third embodiment.

### DETAILED DESCRIPTION

According to embodiments of the present invention, provided are liquid immersion exposure apparatuses. A liquid immersion exposure apparatus is configured to include a table, a plate, an illumination unit, an exposure position movement unit, and relative position change units. A to-be-exposed substrate is mounted on the table. An opening portion surrounding a circumferential edge portion of the substrate mounted on the table is installed in the plate. The illumination unit forms a liquid immersion area filled with liquid immersion water at an exposure position of the substrate mounted on the table, and the illumination unit illuminates an exposure light beam on the exposure position through the liquid immersion area. The exposure position movement unit moves the exposure position. The relative position change units change a relative position between the plate and the table.

Hereinafter, the liquid immersion exposure apparatus according to the embodiments will be described in detail with reference to the attached drawings. The present invention is not limited to the embodiments.

### First Embodiment

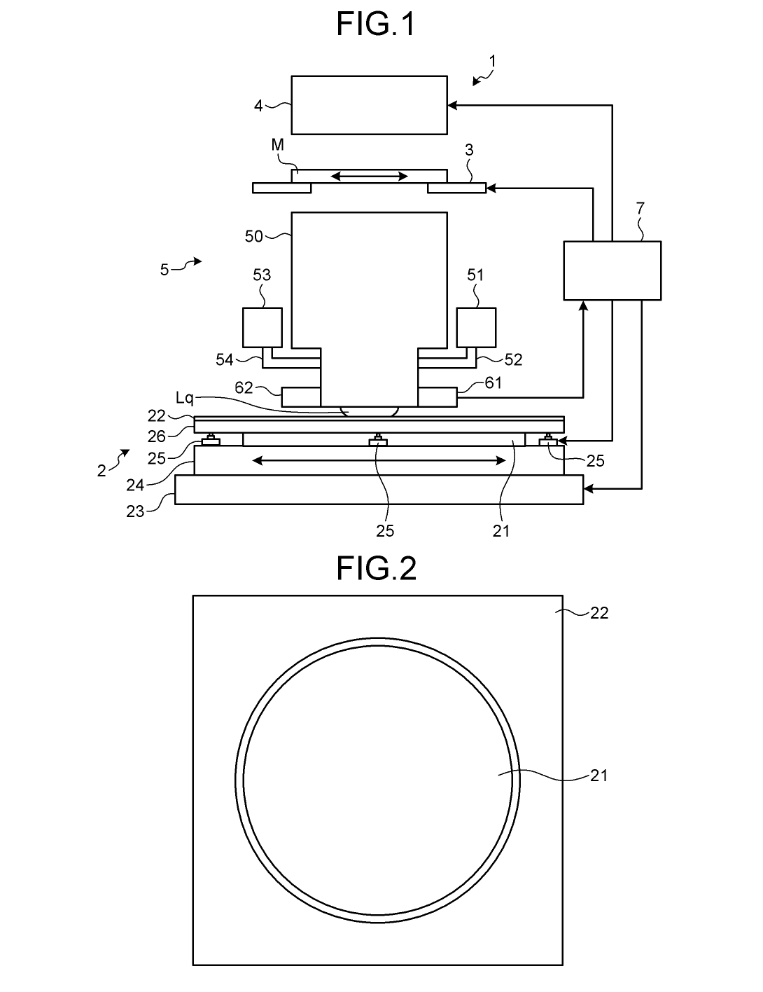

FIG. 1 is a diagram illustrating a liquid immersion exposure apparatus 1 according to a first embodiment. FIG. 2 is a top diagram illustrating a table 21 and a plate 22 of a liquid immersion exposure apparatus 1 according to the first embodiment. As illustrated in FIG. 1, the liquid immersion exposure apparatus 1 is configured to include a substrate stage 2, a mask stage 3, a light source unit 4, an illumination unit 5, and a controller 7.

The substrate stage 2 is a unit which holds a to-be-exposed substrate (hereinafter, referred to as a “wafer”) and moves the exposure position of the wafer with respect to the illumination unit 5 by moving the wafer in an arbitrary direction (forward, backward, leftward, and rightward direction) in a plane including the exposure surface of the wafer. The substrate stage 2 is configured to include an exposure position movement unit 23, a stage main body 24, relative position change units 25, a table 21, a plate holder 26, and a plate 22.

The exposure position movement unit 23 is a driving unit which is installed on, for example, a horizontal floor or the like and moves the stage main body 24 installed at the upper surface side in an arbitrary direction (forward, backward, leftward, and rightward direction) in the horizontal plane according to control of the controller 7. In the substrate stage 2, the exposure position of the wafer with respect to the illumination unit 5 is moved by allowing the exposure position movement unit 23 to move the stage main body 24.

The stage main body 24 is a plate-shaped member which is installed on the upper surface side of the exposure position movement unit 23 and is slidably moved on the horizontal plane in the forward, backward, leftward, and rightward directions with respect to the exposure position movement unit 23. The relative position change units 25 and the table 21 are installed on the upper surface of the stage main body 24. The table 21 is a water chuck which sucks and holds the to-be-exposed wafer mounted on the upper surface. As illustrated in FIG. 2, the table 21 has a substantially circular upper surface as seen from the upper surface.

A plurality of the relative position change units 25 are driving units which are installed so as to surround the table 21 on the upper surface of the stage main body 24 and supports the plate holder 26 from the lower surface side and moves the plate holder 26 in the forward, backward, leftward, and rightward directions and in the upward and downward directions according to control of the controller 7.

As illustrated in FIG. 2, the plate 22 of which the lower surface side is supported by the relative position change units 25 is a plate-shaped member where an opening portion having a circular shape as seen from the upper surface is installed to surround the upper surface of the table 21. The to-be-exposed wafer is mounted and held on the upper surface of the table 21 in a state where the circumferential edge portion is surrounded by an inner circumferential surface of the opening portion in the plate 22.

In addition, in the substrate stage 2, the relative position between the exposure surface (upper surface) of the wafer and the upper surface of the plate 22 in the direction parallel to the normal line of the wafer mounted on the table 21 is changed by allowing the relative position change units 25 to lift up and down the plate holder 26. Therefore, the relative position between the wafer and the plate 22 in the upward and downward directions as seen from the side surface is changed.

In addition, in the substrate stage 2, the relative position between the wafer and the plate 22 in the direction perpendicular to the normal line of the wafer mounted on the table 21 is changed by allowing the relative position change units 25 to move the plate holder 26 in the forward, backward, leftward, and rightward directions. Therefore, the width of a gap between the outer circumferential surface of the wafer mounted on the table 21 and the inner circumferential surface of the opening portion in the plate 22 is changed.

The illumination unit 5 is a unit which illuminates an exposure light beam on the wafer mounted on the table 21 through the liquid immersion water Lq. The illumination unit 5 is configured to include a case 50, a liquid immersion water supply unit 51, a liquid immersion water recovery unit 53, and position detection units 61 and 62.

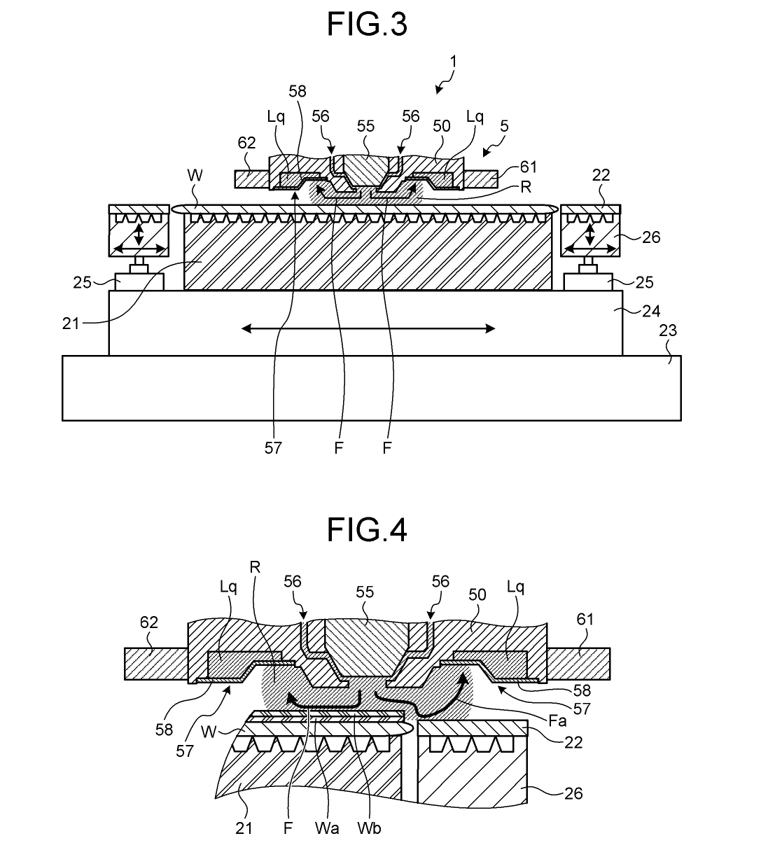

The case 50 contains a plurality of lenses (not illustrated) which reduce the device pattern, which is projected by the exposure light beam incident through a reticle M retained by the mask stage 3, with a predetermined magnification ratio. The case 50 includes a projection lens 55 (refer to FIG. 3) which projects the exposure light beam on the wafer in an inner portion of the side facing the substrate stage 2. In addition, an example of the structure in the vicinity of the projection lens 55 will be described later with reference to FIG. 3.

The liquid immersion water supply unit 51 is a feed pump which supplies the liquid immersion water Lq as ultrapure water to the area in the vicinity of the projection lens 55. The liquid immersion water supply unit 51 is connected through a liquid immersion water supply pipe 52 to the case 50 to supply the liquid immersion water Lq to the area in the vicinity of the projection lens 55 through the inner portion of the liquid immersion water supply pipe 52 and the inner portion of the case 50.

The liquid immersion water recovery unit 53 is a drainage pump which recovers the liquid immersion water Lq from the area in the vicinity of the projection lens 55. The liquid immersion water recovery unit 53 is connected through a liquid immersion water recovery pipe 54 to the case 50 to recover the liquid immersion water Lq from the area in the vicinity of the projection lens 55 through the inner portion of the case 50 and the inner portion of the liquid immersion water recovery pipe 54.

The position detection units 61 and 62 are sensors which detect the position of the wafer mounted on the table 21 and the position of the plate 22. For example, focus sensors used for focusing on the device pattern projected on the wafer can be also used as the position detection units.

The position detection units 61 and 62 emit a laser beam on the upper surface of, for example, the wafer or the table 21 from the inclined upper side and receive the laser beam reflected by the wafer or the table 21. Next, the position detection units 61 and 62 calculate each distance from the end surface of the side of the case 50 facing the substrate stage 2 to the upper surface of the wafer or the plate 22 based on an emitting angle and a receiving angle of the laser beam and output the distance to the controller 7.

In addition, the position detection units 61 and 62 calculate the width of the gap between the outer circumferential surface of the wafer mounted on the plate 22 and the inner circumferential surface of the opening portion in the plate 22 based on the emitting angle and the receiving angle of the laser beam described above and output the width to the controller 7.

The mask stage 3 is a driving unit which retains the reticle M where the device pattern to be transferred to the wafer is patterned and moves the reticle M according to control of the controller 7. The mask stage 3 moves the reticle M in the movement direction and the movement speed in synchronization with the movement of the wafer by the substrate stage 2.

The light source unit 4 is a projection unit which emits a laser beam toward the reticle M to project an exposure light beam on the wafer through the reticle M, the inner portion of the case 50, and the liquid immersion water Lq. The light source unit 4 is, for example, an eximer laser and emits a laser beam according to control of the controller 7. In addition, the light source unit 4 is not limited to the eximer laser, but it may be other projection units projecting an arbitrary exposure light beam.

The controller 7 is a control unit which controls overall operations of the liquid immersion exposure apparatus 1 and is, for example, a CPU (Central Processing Unit). The controller 7 allows the light source unit 4 to perform projection of the exposure light beam and controls operations of the mask stage 3 and the substrate stage 2 to synchronously move the reticle M and the wafer. Therefore, the entire exposure surface of the wafer is scanned by the exposure light beam projected beyond the reticle M, and the device pattern which is patterned on the reticle M is transferred to the exposure surface.

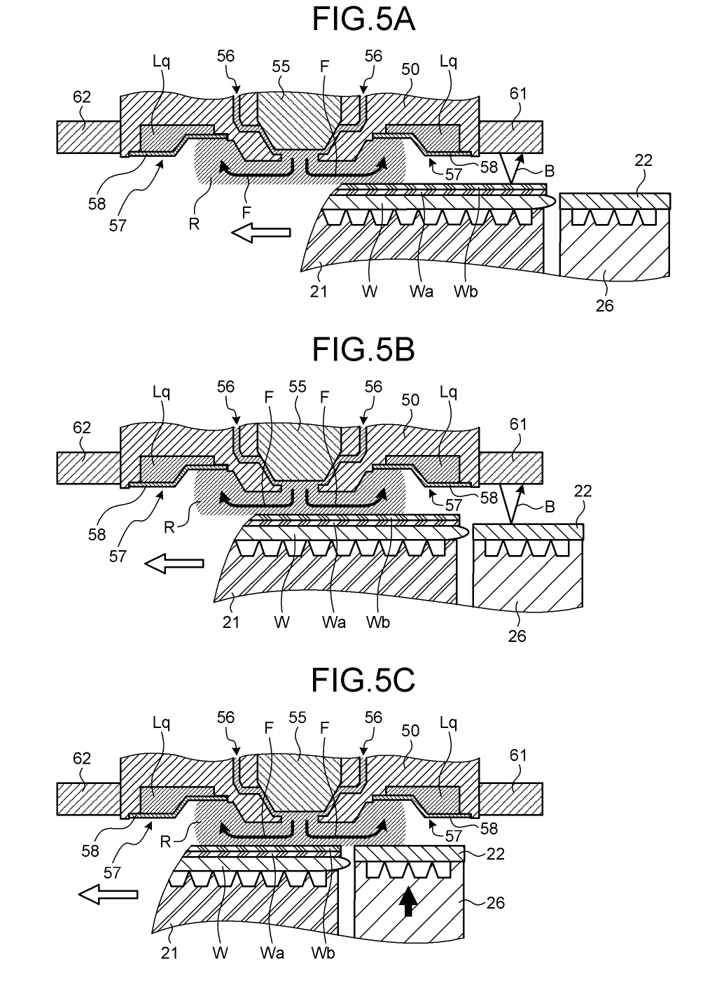

At this time, the controller 7 controls operations of the relative position change units 25 based on a result of detection of the position detection units 61 and 62 so that the occurrence of turbulence in the liquid immersion water Lq is suppressed when the exposure light beam traverses the gap between the outer circumferential surface of the wafer and the inner circumferential surface of the opening portion in the plate 22. In addition, an example of a situation where turbulence occurs will be described later with reference to FIG. 4, and an example of the operations of the relative position change units 25 for suppressing the occurrence of turbulence will be described later with reference to FIGS. 5A to 5C.

Next, the structure in the vicinity of the projection lens 55 in the illumination unit 5 will be described with reference to FIG. 3. FIG. 3 is a diagram illustrating the structure in the vicinity of the projection lens 55 according to the first embodiment. Herein, the same components of the configuration illustrated in FIG. 3 as those of the configuration illustrated in FIG. 1 are denoted by the same reference numerals illustrated in FIG. 1, and the description thereof will not be made.

In addition, FIG. 3 illustrates a schematic section of the vicinity of the projection lens 55 in the illumination unit 5, the table 21, the plate 22, the plate holder 26, and the wafer W and a schematic section of the exposure position movement unit 23, the stage main body 24, and the relative position change units 25.

As illustrated in FIG. 3, the projection lens 55 which projects the exposure light beam on the exposure surface of the wafer W is installed in the inner center of the side of the case 50 of the illumination unit 5 facing the exposure surface of the wafer W. In addition, a liquid immersion water supply channel 56 which supplies the liquid immersion water Lq is installed in the vicinity of the projection lens 55 so as to surround the projection lens 55.

The one end of the liquid immersion water supply channel 56 facing the exposure surface of the wafer W is opened, and the other end thereof is connected to the liquid immersion water supply pipe 52 illustrated in FIG. 1. The liquid immersion water Lq is supplied from the liquid immersion water supply channel 56 to the space between the projection lens 55 and the exposure position of the upper surface of the wafer W.

In addition, a liquid immersion water recovery orifice 57 through which the liquid immersion water Lq is recovered from the space between the projection lens 55 and the exposure position on the upper surface of the wafer W is installed in the end surface of the side of the case 50 facing the exposure surface of the wafer W so as to surround the liquid immersion water supply channel 56. In addition, a filter 58 having a mash shape is installed in the opening portion of the liquid immersion water recovery orifice 57.

The illumination unit 5 forms a water flow F of the liquid immersion water Lq in the space between the projection lens 55 and the exposure position on the upper surface of the wafer W by simultaneously performing supplying the liquid immersion water Lq from the liquid immersion water supply channel 56 and recovering the liquid immersion water Lq from the liquid immersion water recovery orifice 57 during the projection of the exposure light beam. Therefore, a liquid immersion area R filled with the liquid immersion water Lq is formed in the space between the projection lens 55 and the exposure position on the upper surface of the wafer W.

Next, in the liquid immersion exposure apparatus 1, the entire exposure surface of the wafer W is scanned by the exposure light beam illuminated through the liquid immersion area R while moving the wafer W by allowing the exposure position movement unit 23 to move the stage main body 24 on the horizontal plane, so that the device pattern is transferred to the exposure surface of the wafer W.

Next, an example of a situation where turbulence of the liquid immersion water Lq occurs in the liquid immersion area will be described with reference to FIG. 4. FIG. 4 is a diagram illustrating an example of a situation where turbulence Fa of the liquid immersion water Lq occurs in the liquid immersion exposure apparatus 1 according to the first embodiment. Herein, the same components of the configuration illustrated in FIG. 4 as those illustrated in FIG. 3 are denoted by the same reference numerals illustrated in FIG. 3, and the description thereof will not be made.

In addition, FIG. 4 illustrates a schematic section of the vicinity of the liquid immersion area R when the exposure light beam together with the liquid immersion area R traverses the gap between the outer circumferential surface of the wafer W mounted on the table 21 and the inner circumferential surface of the opening portion in the plate 22.

In general, in a procedure of manufacturing a semiconductor device, a film formation process for forming thin films of a semiconductor, insulator, a metal, or the like on the upper surface of the wafer W and an exposure process for transferring the device pattern to the formed thin films are repetitively performed.

Therefore, as illustrated in FIG. 4, in the procedure of manufacturing the semiconductor device, in some cases, as thin films Wa and Wb are sequentially laminated on the upper surface of the wafer W, a difference between the height position of the exposure surface (herein, the upper surface of the thin film Wb) and the height position of the upper surface of the plate 22 is increased. In addition, hereinafter, in the case where the thin films Wa and Wb are formed on the upper surface of the wafer W, thin films Wa and Wb and the wafer W are collectively referred to as a wafer W.

In this case, if the exposure light beam together with the liquid immersion area R traverses the gap between the outer circumferential surface of the wafer W mounted on the table 21 and the inner circumferential surface of the opening portion in the plate 22, the turbulence Fa of the liquid immersion water Lq may occur in the liquid immersion area R due to the step difference between the upper surface of the thin film Wb and the upper surface of the plate 22.

In addition, in the case where the turbulence Fa of the liquid immersion water Lq occurs in the liquid immersion area R, bubbles are mixed in the turbulence Fa, a refractive index with respect to the exposure light beam is changed due to the mixed bubbles, so that defects may occurs in the device pattern transferred to the exposure surface of the wafer W.

In addition, due to the turbulence Fa of the liquid immersion water Lq occurring in the liquid immersion area R, the liquid immersion water Lq is not recovered but remains on the upper surface of the wafer W after the exposure, and the remaining liquid immersion water Lq deforms a photosensitive material (not illustrated) coated on the upper surface of the wafer W, so that defects may occur in the transferred device pattern.

In addition, even in the state where the thin films Wa and Wb are not formed on the upper surface of the wafer W, due to unbalance of processing accuracy of the plate 22 or unbalance of attachment accuracy of the plate 22, a large difference may occur between the height position of the exposure surface of the wafer W and the height position of the upper surface of the plate 22. In this case, similarly to the situation illustrated in FIG. 4, the turbulence Fa of the liquid immersion water Lq occurs in the liquid immersion area R, so that defects may occur in the device pattern transferred to the wafer W.

Therefore, in the liquid immersion exposure apparatus 1, the controller 7 controls the operations of the relative position change units 25 based on the forward, backward, leftward, rightward, upward, and downward positions of the wafer W and the plate 22 detected by position detection units 61 and 62 to suppress the occurrence of turbulence Fa in the liquid immersion water Lq. Hereinafter, an example of operations of the liquid immersion exposure apparatus 1 for suppressing the occurrence of turbulence Fa in the liquid immersion water Lq will be described with reference to FIGS. 5A to 5C.

FIGS. 5A to 5C are diagrams illustrating an example of operations of the liquid immersion exposure apparatus 1 according to the first embodiment. Herein, the same components of the configuration illustrated in FIGS. 5A to 5C as those illustrated in FIG. 4 are denoted by the same reference numerals illustrated in FIG. 4, and the description thereof will not be made. In addition, herein, described is a case where a large difference occurs between the height position of the exposure surface of the wafer W including the thin films Wa and Wb and the height position of the upper surface of the plate 22 and the wafer W is moved in the direction indicated by a white arrow.

The controller 7 of the liquid immersion exposure apparatus 1 stores a threshold value (hereinafter, referred to as a “height threshold value”) with respect to the difference between the height position of the exposure surface of the wafer W mounted on the table 21 and the height position of the upper surface of the plate 22 in advance. The height threshold value is determined by performing experiment or simulation in advance.

For example, while the difference between the height position of the exposure surface of the wafer W mounted on the table 21 and the height position of the upper surface of the plate 22 is sequentially changed, the liquid immersion exposure is performed. As a result, the maximum value of the difference between the height position of the exposure surface of the wafer W where no defect occurs in the transferred device pattern and the height position of the upper surface of the plate 22 is determined as the height threshold value.

In addition, the controller 7 stores a threshold value (hereinafter, referred to as a “gap threshold value”) with respect to the width of the gap between the wafer W mounted on the table 21 and the plate 22. The gap threshold value is also determined by performing experiment or simulation in advance.

For example, while the width of the gap between the wafer W mounted on the table 21 and the plate 22 is sequentially changed, the liquid immersion exposure is performed. As a result, the maximum value of the width of the gap between the wafer W where no defect occurs in the transferred device pattern and the plate 22 is determined as the gap threshold value.

Next, in the liquid immersion exposure apparatus 1, in the case where the liquid immersion exposure is actually performed, as illustrated in FIG. 5A, at the time before the liquid immersion area R traverses the gap between the wafer W and the plate 22, the position detection unit 61 illuminates a laser beam B on the exposure surface of the wafer W to detect the height position of the exposure surface and outputs the height position to the controller 7.

After that, as illustrated in FIG. 5B, in the case where the wafer W is further moved to the position where the position detection unit 61 and the plate 22 face each other in the direction indicated by the white arrow, the position detection unit 61 detects the height position of the plate 22 and outputs the height position to the controller 7.

Next, the controller 7 calculates the difference between the height position of the exposure surface of the wafer W detected in the situation illustrated in FIG. 5A and the height position of the upper surface of the plate 22 detected in the situation illustrated in FIG. 5B and allows the relative position change units 25 (refer to FIG. 3) to operate so that the difference is reduced.

For example, as illustrated in FIG. 5C, the controller 7 allows the relative position change units 25 to lift up the plate holder 26 and the plate 22 so that the difference between the height position of the exposure position of the wafer W and the height position of the upper surface of the plate 22 is to less than the height threshold value described above.

Therefore, in the liquid immersion exposure apparatus 1, when the liquid immersion area R traverses the gap between the outer circumferential surface of the wafer W and the inner circumferential surface of the opening portion in the plate 22, the occurrence of turbulence Fa in the liquid immersion water Lq can be suppressed by the liquid immersion area R. Therefore, according to the liquid immersion exposure apparatus 1, the occurrence of defects in the device pattern transferred to the wafer W due to the turbulence Fa of the liquid immersion water Lq can be suppressed.

In addition, herein, although the case where the height position of the exposure surface of the wafer W is higher than the height position of the upper surface of the plate 22 is described, there may be a case where the height position of the exposure surface of the wafer W is lower than the height position of the upper surface of the plate 22. In this case, the controller 7 allows the relative position change units 25 to lift down the plate holder 26 and plate 22 so that the difference between the height position of the exposure surface of the wafer W and the height position of the upper surface of the plate 22 is less than the height threshold value.

Therefore, in the liquid immersion exposure apparatus 1, even in the case where the height position of the exposure surface of the wafer W is lower than the height position of the upper surface of the plate 22, the occurrence of defects in the device pattern transferred to the wafer W due to the turbulence Fa of the liquid immersion water Lq can be suppressed.

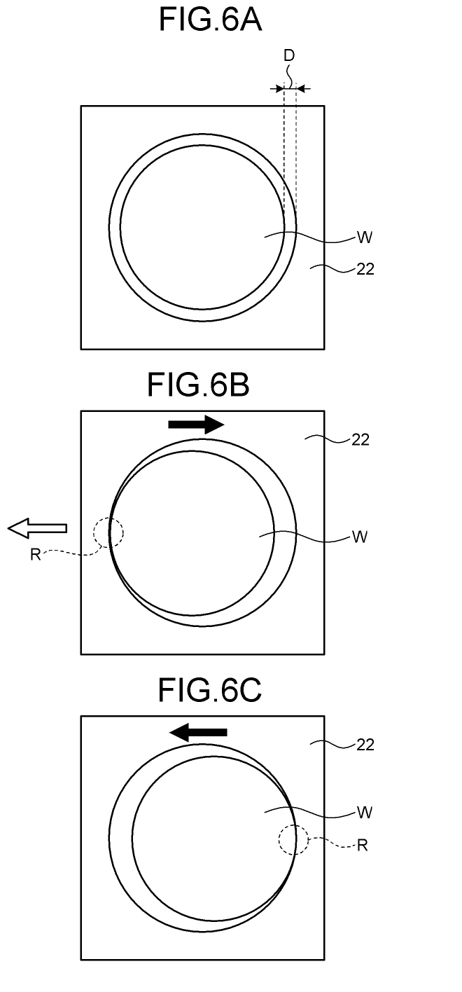

Next, in the case where the width of the gap between the wafer W mounted on the table 21 and the plate 22 is equal to or larger than the gap threshold value, an example of operations performed by the liquid immersion exposure apparatus 1 will be described with reference to FIGS. 6A to 6C. FIGS. 6A to 6C are diagrams illustrating an example of operations of the liquid immersion exposure apparatus 1 according to the first embodiment. In addition, FIGS. 6A to 6C are diagrams illustrating the wafer W and the plate 22 during the liquid immersion exposure as seen from the top surface.

As illustrated in FIG. 6A, in the liquid immersion exposure apparatus 1, there is a case where the width of the gap between the wafer W and the plate 22 becomes a width D larger than the gap threshold value due to the size of the exposure surface of the wafer W. In this case, the wafer W is deformed due to vaporization heat of the liquid immersion water Lq dropped downward from the gap, so that defects may occurs in the transferred device pattern.

Therefore, as illustrated in FIG. 6B, the controller 7 of the liquid immersion exposure apparatus 1 allows the exposure position movement unit 23 to move the plate 22 and the wafer W in the direction indicated by a white arrow, and in the case where the liquid immersion area R traverses the space between the one end of the wafer W and the plate 22, the width of the gap just below the liquid immersion area R is reduced.

More specifically, the controller 7 controls the operations of the relative position change units 25 independently of the control of operations of the exposure position movement unit 23 to move the plate 22 in the direction indicated by a black arrow illustrated in FIG. 6B, so that the width of the gap between the wafer W and the plate 22 just below the liquid immersion area R is less than the gap threshold value. Therefore, in the liquid immersion exposure apparatus 1, the drop of the liquid immersion water Lq downward from the gap between the wafer W and the plate 22 just below the liquid immersion area R can be prevented.

After that, the controller 7 continuously performs exposure of the wafer W while allowing the exposure position movement unit 23 to further move the plate 22 and the wafer W in the direction indicated by a white arrow illustrated in FIG. 6B. In addition, as illustrated in FIG. 6C, in the case where the liquid immersion area R traverses the space between the other end of the wafer W and the plate 22, the controller 7 reduces the width of the gap just below the liquid immersion area R.

In other words, the controller 7 controls the operations of the relative position change units 25 independently of the control of the operations of the exposure position movement unit 23 to move the plate 22 in the direction indicated by a black arrow illustrated in FIG. 6C, so that the width of the gap between the wafer W and the plate 22 just below the liquid immersion area R is less than the gap threshold value. Therefore, in the liquid immersion exposure apparatus 1, the drop of the liquid immersion water Lq downward from the gap between the wafer W and the plate 22 just below the liquid immersion area R can be prevented.

In this manner, in the liquid immersion exposure apparatus 1, since the drop of the liquid immersion water Lq downward from the gap between the wafer W and the plate 22 just below the liquid immersion area R can be prevented, the occurrence of the defects in the transferred device pattern can be suppressed.

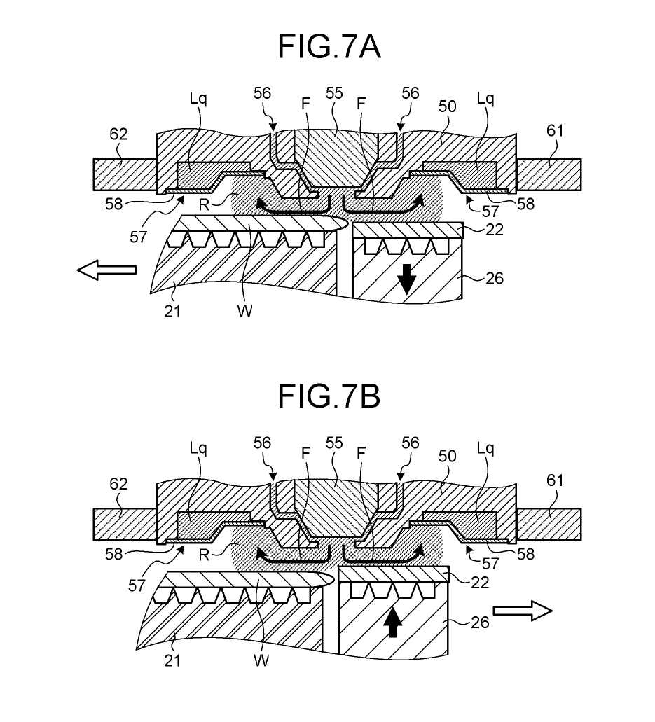

Next, the control of the controller 7 which allows the relative position change units 25 to change the relative position between the wafer W and the plate 22 according to the direction where the exposure light beam together with the liquid immersion area R traverses the gap between the outer circumferential surface of the wafer W and the inner circumferential surface of the opening portion in the plate 22 will be described with reference to FIGS. 7A and 7B.

FIGS. 7A and 7B are diagrams illustrating an example of operations of the liquid immersion exposure apparatus 1 according to the first embodiment. In addition, FIG. 7A illustrates the case where the liquid immersion area R moves from the wafer W to the plate 22, and FIG. 7B illustrates the case where the liquid immersion area R moves from the plate 22 to the wafer W.

As illustrated in FIG. 7A, in the case where the wafer W and the plate 22 are moved in the direction indicated by a white arrow and the liquid immersion area R moves from the wafer W to the plate 22, the controller 7 lifts down the plate 22 to a position lower than the wafer W in a range of less than the height threshold value.

Therefore, in the liquid immersion exposure apparatus 1, in the case where the liquid immersion area R moves from the wafer W to the plate 22, since the liquid immersion water Lq on the wafer W can be drawn toward the upper surface side of the plate 22, the remaining of the liquid immersion water Lq on the upper surface of the wafer W can be suppressed. Therefore, according to the liquid immersion exposure apparatus 1, the occurrence of defects in the transferred device pattern can be suppressed.

In addition, in some environment such as atmospheric pressure or a current of air where the liquid immersion exposure apparatus 1 is installed, in the case where the liquid immersion area R moves from the wafer W to the plate 22, if the plate 22 is lifted down to a position lower than the wafer W, some of the liquid immersion water Lq may remain on the wafer W. In this case, in the case where the liquid immersion area R moves from the wafer W to the plate 22, the controller 7 lifts up the plate 22 to a position higher than the wafer W in a range of less than the height threshold value.

In addition, as illustrated in FIG. 7B, in the case where the wafer W and the plate 22 are moved in the direction indicated by a white arrow and the liquid immersion area R moves from the plate 22 to the wafer W, the controller 7 lifts up the plate 22 to a position higher than the wafer W in a range of less than the height threshold value.

Therefore, in the case where the liquid immersion area R moves from the plate 22 to the wafer W, since the liquid immersion water Lq on the plate 22 can be drawn toward the upper surface side of the wafer W, the exposure position on the upper surface of the wafer W can be speedily filled with the liquid immersion water Lq. Therefore, according to the liquid immersion exposure apparatus 1, the transferring of the device pattern can be speedily started.

In addition, in some environment such as atmospheric pressure or a current of air where the liquid immersion exposure apparatus 1 is installed, in the case where the liquid immersion area R moves from the plate 22 to the wafer W, if the plate 22 is lifted up to a position higher than the wafer W, some of the liquid immersion water Lq may remain on the wafer W. In this case, in the case where the liquid immersion area R moves from the plate 22 to the wafer W, the controller 7 lifts down the plate 22 to a position lower than the wafer W in a range of less than the height threshold value.

As described above, the liquid immersion exposure apparatus according to the first embodiment is configured to include a table, a plate, an illumination unit, an exposure position movement unit, and relative position change units. A to-be-exposed substrate is mounted on the table. An opening portion surrounding a circumferential edge portion of the substrate mounted on the table is installed in the plate.

The illumination unit forms a liquid immersion area filled with liquid immersion water at an exposure position of the substrate mounted on the table and illuminates an exposure light beam on the exposure position through the liquid immersion area. The exposure position movement unit moves the exposure position by the exposure light beam. The relative position change units change a relative position between the table and the plate. According to the configuration, the liquid immersion exposure apparatus according to the first embodiment can suppress the occurrence of defects in a device pattern transferred to the to-be-exposed substrate.

### Second Embodiment

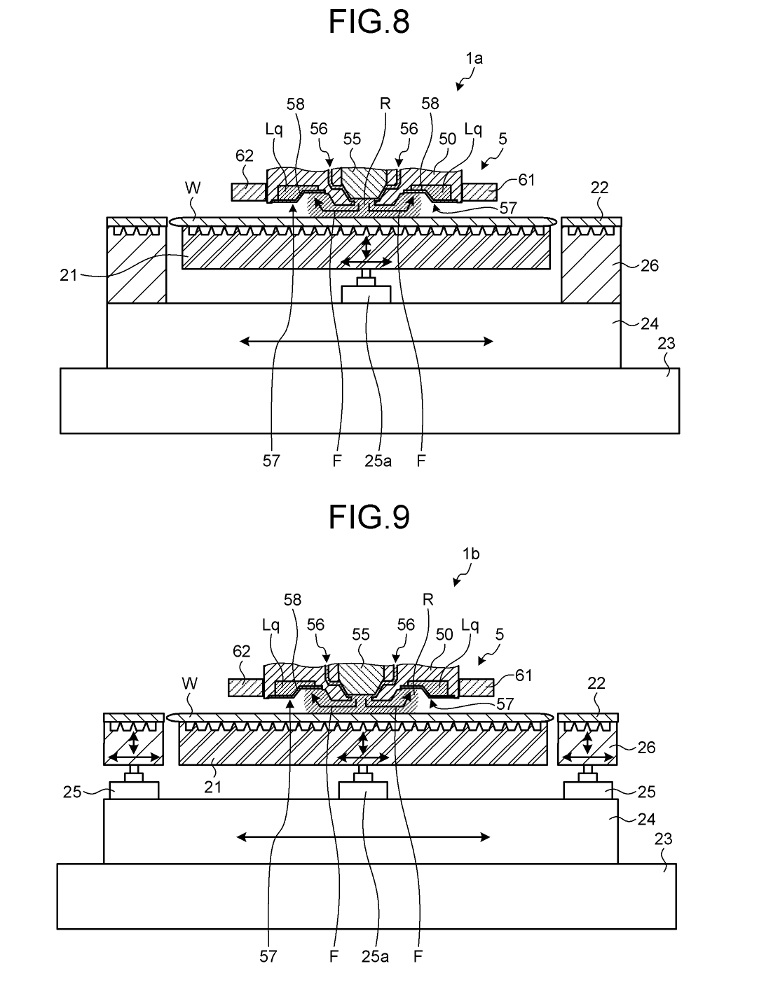

Next, a liquid immersion exposure apparatus according to a second embodiment will be described with reference to FIG. 8. FIG. 8 is a diagram illustrating the liquid immersion exposure apparatus 1a according to the second embodiment. Herein, the same components of the configuration illustrated in FIG. 8 as those illustrated in FIG. 3 are denoted by the same reference numerals illustrated in FIG. 3, and the description thereof will not be made.

As illustrated in FIG. 8, the liquid immersion exposure apparatus 1a is different from the liquid immersion exposure apparatus 1 illustrated in FIG. 3 in that the plate holder 26 is fixed to the stage main body 24 and relative position change units 25a are installed to move the table 21 in the forward, backward, leftward, rightward, upward, and downward directions.

In the liquid immersion exposure apparatus 1a, the relative position change units 25a are allowed to operate according to the control of the controller 7 (refer to FIG. 1), so that the difference between the height position of the upper surface of the wafer W mounted on the table 21 and the height position of the upper surface of the plate 22 is reduced. In addition, the relative position change units 25a reduce the width of the gap between the wafer W and the plate 22 just below the liquid immersion area R.

In this manner, in the liquid immersion exposure apparatus 1a, the plate 22 side thereof is fixed, and the table 21 side thereof is moved according to the control of the operations thereof independently of the control of the operations of the exposure position movement unit 23. Therefore, according to the second embodiment, the liquid immersion exposure apparatus 1a can suppress the occurrence of defects in the device pattern transferred to the to-be-exposed substrate.

### Third Embodiment

Next, a liquid immersion exposure apparatus according to the third embodiment will be described with reference to FIG. 9. FIG. 9 is a diagram illustrating a liquid immersion exposure apparatus 1b according to the third embodiment. Herein, the same components of the configuration illustrated in FIG. 9 as those illustrated in FIG. 3 are denoted by the same reference numerals illustrated in FIG. 3, and the description thereof will not be made.

As illustrated in FIG. 9, the liquid immersion exposure apparatus 1b is different from the liquid immersion exposure apparatus 1 illustrated in FIG. 3 in that the relative position change units 25a illustrated in FIG. 8 in addition to the relative position change units 25 illustrated in FIG. 3 are installed.

In this manner, the liquid immersion exposure apparatus 1b moves both of the plate 22 and the table 21 by control of operations independently of the control of operations of the exposure position movement unit 23. Therefore, the liquid immersion exposure apparatus 1b can more finely adjust the height position of the upper surface of the wafer W mounted on the table 21, the height position of the upper surface of the plate 22, and the width of the gap between the wafer W and the plate 22 just below the liquid immersion area R. Therefore, according to the third embodiment, the liquid immersion exposure apparatus 1b can more securely suppress the occurrence of defects in the device pattern transferred to the to-be-exposed substrate.

In addition, in the first to third embodiments described above, although the controller of the liquid immersion exposure apparatus automatically changes the relative position between the table and the wafer by controlling the operations of the relative position change units based on a result of the detection of the position detection units, the automatic control of the operations of the relative position change units is not a requisite.

For example, the difference between the height position of the upper surface of the wafer and the height position of the upper surface of the plate and the width of the gap between the wafer and the plate may be measured in advance. Next, in the case where the liquid immersion water traverses the space between the wafer and the plate, the operations of the relative position change units may be manually controlled so that the difference in the height position and the width of the gap which are measured in advance by an operator or the like are reduced.

According to the configuration, if the relative position change units are installed in a liquid immersion exposure apparatus of the related art, the occurrence of defects in the device pattern transferred to the to-be-exposed substrate can be more securely suppressed without change of the process of the controller.

In addition, in the liquid immersion exposure apparatus according to the first to third embodiments described above, the controller may be configured so that the changed amount of the relative position between the wafer and the plate by the relative position change units is changed according to a wafer scanning speed of the exposure light beam.

For example, the controller may be configured so that, as the wafer scanning speed of the exposure light beam is increased, the height threshold value and the gap threshold value described above are decreased. According to the configuration, in the case where the wafer scanning speed of the exposure light beam is allowed to be increased, the occurrence of defects in the transferred device pattern can be more securely suppressed. On the other hand, in the case where the wafer scanning speed of the exposure light beam is allowed to be decreased, a process of changing the relative position between the wafer and the plate into an unnecessarily large amount may not be performed.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A liquid immersion exposure apparatus comprising:
a table which is mounted on a to-be-exposed substrate;
a plate where an opening portion surrounding a circumferential edge portion of the substrate mounted on the table is installed;
an illumination unit which forms a liquid immersion area filled with liquid immersion water at an exposure position of the substrate mounted on the table and illuminates an exposure light beam on the exposure position through the liquid immersion area;
an exposure position movement unit which moves the exposure position; and
a relative position change unit which changes a relative position between the table and the plate.

2. The liquid immersion exposure apparatus according to claim 1, wherein the relative position change unit changes the relative position in a direction parallel to a normal line of the substrate mounted on the table.

3. The liquid immersion exposure apparatus according to claim 1, wherein the relative position change unit changes the relative position in a direction perpendicular to a normal line of the substrate mounted on the table.

4. The liquid immersion exposure apparatus according to claim 1, comprising:
a position detection unit which detects a position of the substrate mounted on the table and a position of the plate; and
a controller which allows the relative position change unit to change the relative position based on the position of the substrate and the position of the plate detected by the position detection unit.

5. The liquid immersion exposure apparatus according to claim 4, wherein the controller allows the relative position change unit to change the relative position according to the direction where the exposure light beam traverses a gap between an outer circumferential surface of the substrate mounted on the table and an inner circumferential surface of the opening portion in the plate.

6. The liquid immersion exposure apparatus according to claim 4, wherein the controller controls the relative position change unit so that a difference between a height position of an exposure surface of the substrate mounted on the table and a height position of an upper surface of the plate is less than a predetermined threshold value.

7. The liquid immersion exposure apparatus according to claim 4, wherein, in the case where the liquid immersion area traverses the opening portion between an outer circumferential surface of the substrate and the plate, the controller controls the relative position change unit so that a width of a gap between the outer circumferential surface of the substrate and the inner circumferential surface of the opening portion in the plate just below the liquid immersion area is less than a predetermined threshold value.

8. The liquid immersion exposure apparatus according to claim 1, wherein a plurality of the relative position change units are installed so as to surround the table, and the relative position change units support a plate holder where, the plate is installed at an upper surface side thereof, from a lower surface side thereof and move the plate holder in forward, backward, leftward, rightward, upward, and downward directions to change the relative position.

9. The liquid immersion exposure apparatus according to claim 4, wherein the controller controls operations of the exposure position movement unit and controls operations of the relative position change unit independently of the control of operations of the exposure position movement unit.

10. The liquid immersion exposure apparatus according to claim 1, wherein, in the case where the liquid immersion area moves from the substrate to the plate, the relative position change unit lifts down the plate to a position lower than the substrate.

11. The liquid immersion exposure apparatus according to claim 1, wherein, in the case where the liquid immersion area moves from the substrate to the plate, the relative position change unit lifts down the plate to a position higher than the substrate.

12. The liquid immersion exposure apparatus according to claim 1, wherein, in the case where liquid immersion area moves from the plate to the substrate, the relative position change unit lifts down the plate to a position higher than the substrate.

13. The liquid immersion exposure apparatus according to claim 1, wherein, in the case where liquid immersion area moves from the plate to the substrate, the relative position change unit lifts down the plate to a position lower than the substrate.

14. The liquid immersion exposure apparatus according to claim 4, wherein the controller uses a focus sensor, which is used for focusing a device pattern to be projected on the substrate, as the position detection unit.

15. The liquid immersion exposure apparatus according to claim 1, wherein the relative position change unit moves the table in forward, backward, leftward, rightward, upward, and downward directions to change the relative position.

16. The liquid immersion exposure apparatus according to claim 1, wherein the relative position change unit moves a plate holder holding the plate and the table in forward, backward, leftward, rightward, upward, and downward directions to change the relative position.

17. The liquid immersion exposure apparatus according to claim 6, wherein the controller allows the relative position change unit to change a changed amount of the relative position according to a movement speed of the exposure position by the exposure position movement unit, so that as the movement speed of the exposure position by the exposure position movement unit is increased, the threshold value is decreased.

18. The liquid immersion exposure apparatus according to claim 7, wherein the controller allows the relative position change unit to change a changed amount of the relative position according to a movement speed of the exposure position by the exposure position movement unit, so that as the movement speed of the exposure position by the exposure position movement unit is increased, the threshold value is decreased.
